(19) United States
(12) Patent Application Publication
(10) Pub. No.: US 2005/0237800 A1
(43) Pub. Date: Oct. 27, 2005

(54) Sector protection circuit for non-volatile semiconductor memory, sector protection method and non-volatile semiconductor memory

(76) Inventor: Kazuhide Kurosaki, Tokyo (JP)

Correspondence Address: Paul J. Winters, 307 Cypress Point Drive, Mountain View, CA, 94043, US

(21) Appl. No.: 11/103,960

(22) Filed: Apr. 12, 2005

Related U.S. Application Data
(63) Continuation of application No. PCT/JP04/05268, filed on Apr. 13, 2004.

(51) Int. Cl. G11C 11/34

(52) U.S. Cl. 365/185.04; 365/189.04

(57) ABSTRACT

A sector protection circuit of the invention has a non-volatile storage section storing data indicating sector protection/unprotection for each sector or each sector group, and a volatile storage section storing data indicating sector protection/unprotection for each sector or each sector group. Normally, each sector or sector group can be protected when data indicative of sector or sector group protection is stored in at least one of the non-volatile storage section and the volatile storage section. When a given command is received in the above normal state, data only in the volatile storage section is enabled.

### CROSS REFERENCE TO RELATED APPLICATION

This is a continuation of International Application No. PCT/JP2004/005268, filed Apr. 13, 2004.

### BACKGROUND OF THE INVENTION

1. Field of the Invention

The present invention relates to a sector protection circuit for protecting data stored in a sector, and a non-volatile semiconductor memory.

2. Description of the Related Art

The flash memory is a non-volatile semiconductor memory that has both the features of the RAM (Random Access Memory) in which data is rewritable, and the features of the ROM (Read Only Memory capable of holding data after power-off. The storage area of the flash memory is a group of units called sectors, and data is erased on the chip or sector basis. The conventional flash memories have a protection function of preventing important programs stored therein such as a boot program from being changed due to a bug that causes malfunction. For example, a flash memory of a boot block type uses a block called boot block for inhibiting hardware-oriented programming and erasing.

A flash memory equipped with the following protection function is known. In this flash memory, the memory area is divided into sectors (or blocks), each of which can be protected or unprotected separately. The sector protecting function is realized by two bits, one of which is a PPB (Persistent Protection Bit) that is a non-volatile cell, and the other is a DPB (Dynamic Protection Bit) that is a volatile cell. The set of PPB and DPB is provided for each of the sectors, and may inhibit hardware-oriented programming and erasing of the corresponding sector.

Rewriting (programming and erasing) of a sector protection command for DPB of the volatile cell can easily be implemented by providing each DPB with a respective command.

Rewriting of the sector protection command for PPB of the non-volatile cell requires a relatively complicated process. More particularly, the writing (sector protection) of PPB can easily be carried out by the command input to the individual target PPB (or by applying a high voltage via a specific input pin), while the once-performed erasing of multiple PPBs (sector unprotection) is required. It should be noted that the once-performed erasing must be performed after programming all the multiple PPBs prior to erasing in order to avoid over-erasing of PPBs.

In addition, the above-mentioned sector protecting function is designed so that, when at least one of PPB and DPB is in the protected state, data in the related sector in the protected state are protected from being rewritten. Once the sector protection by PPB is set, data in the sector cannot be rewritten unless the PPBs are erased all at once. In an alternative, the high voltage may be applied to the specific pin to temporarily release the sector protection. However, in practice, the alternative has a difficulty in execution in the on-board state due to the use of the high voltage.

### SUMMARY OF THE INVENTION

The present invention has been made taking the above-mentioned problems into consideration and has an object of providing a sector protection circuit for a non-volatile semiconductor memory capable of rewriting a sector without erasing PPBs, and a non-volatile semiconductor memory equipped with the sector protection circuit.

According to an aspect of the present invention, there is provided a sector protection circuit including: a non-volatile storage section storing data indicating sector protection/unprotection for each sector or each sector group; a volatile storage section storing data indicating sector protection/unprotection for each sector or each sector group; and a circuit enabling only the data stored in the volatile storage section in response to a first command related to a sector or sector group in a state in which said sector or sector group is protected from programming and erasing when at least one of the non-volatile and volatile storage sections stores data indicating that said sector or sector group should be protected.

The circuit may include a circuit that performs a logical operation on the data stored in the non-volatile storage section, the data stored in the volatile storage section, and a signal associated with the first command.

The circuit may include a circuit that blocks a transfer of the data from the non-volatile storage section when receiving the first command.

The circuit may disable the first command when a signal that inhibits the data in the non-volatile storage section from being rewritten is set.

The circuit may include a circuit that performs a logical operation on the data in the non-volatile storage section, the data in the volatile storage section, a signal associated with the first command, and another signal associated with a second command that inhibits the data in the non-volatile storage section from being rewritten.

All data in the non-volatile storage section may be erased concurrently.

According to another aspect of the present invention, there is provided a sector protection circuit including: a non-volatile storage section storing data indicating sector protection/unprotection for each sector or each sector group; a volatile storage section data indicating sector protection/unprotection for each sector or each sector group; and a circuit that disables data stored in the non-volatile storage section and enables data in the volatile storage section when receiving a first command. The circuit may disable the first command when receiving a second command. The second command may inhibit the data in the non-volatile storage section from being rewritten.

The present invention includes a semiconductor device equipped with the above sector protection circuit.

According to yet another aspect of the present invention, there is provided a sector protection method comprising the steps of: protecting, in the absence of a given command, a sector or sector group when data indicating that said sector or sector group should be protected is stored in at least one of a non-volatile storage section storing data indicating sector protection/unprotection for each sector or each sector group and a volatile storage section storing data indicating sector protection/unprotection for each sector or each sector group; and enabling only data in the volatile storage section in response to the given command input.

The above method may be configured so as to have a step of disabling the given command when receiving another command that inhibits the data in the non-volatile storage section from being rewritten.

According to the present invention, there is no need to perform erasing of PPB (non-volatile memory section) in the sector protection circuit in order to execute the rewriting of the sector, and easy rewriting by a command input can be performed.

### BRIEF DESCRIPTION OF THE DRAWINGS

Preferred embodiments of the present invention will be described in detail based on the following figures, wherein:

FIG. 1 is a circuit diagram of a sector protection circuit provided in a non-volatile semiconductor memory according to the present invention;

FIG. 2 is a flowchart of a sector rewriting sequence of rewriting a sector in which sector protection information is stored in a PPB cell associated with the sector to be rewritten;

FIG. 3 is a block diagram of a non-volatile semiconductor memory in which the sector protection circuit of the present invention is incorporated;

FIG. 4 is a circuit diagram of an individual DPB that forms a DPB circuit of the present invention;

FIG. 5 is a circuit diagram of an individual PPB that forms a PPB circuit of the present invention; and

FIG. 6 is a timing chart of an operation of the sector protection circuit according to the present invention.

### DESCRIPTION OF THE PREFERRED EMBODIMENTS

A description will now be given, with reference to the accompanying drawings, of embodiments of the present invention. Although a sector protection circuit that will be described below is applicable to any type of non-volatile memories, the memory device described below is a flash memory.

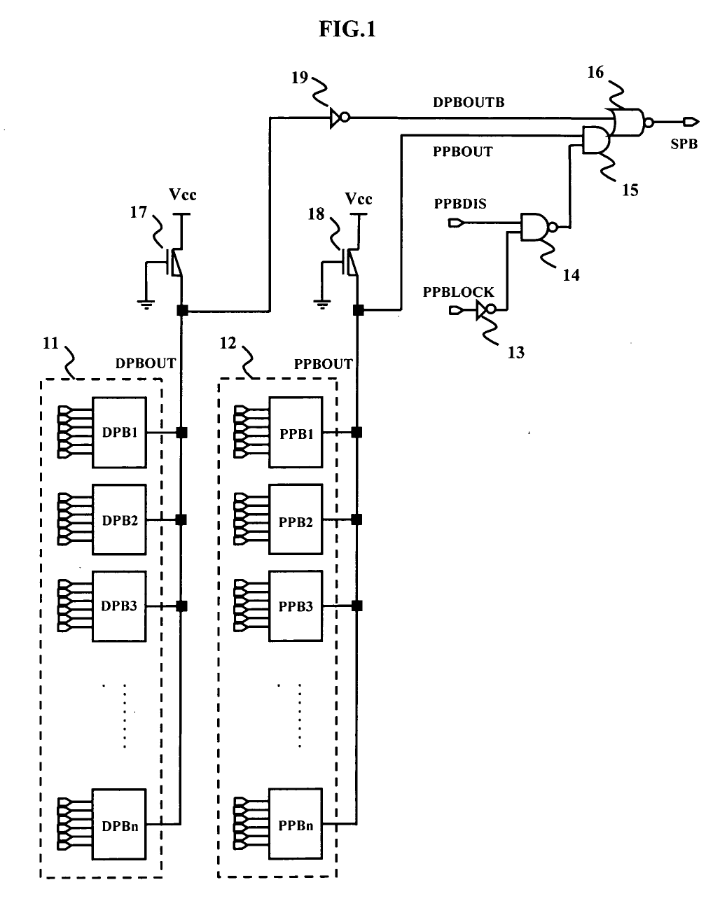

FIG. 1 is a circuit diagram of an outline of the sector protection circuit embedded in the non-volatile semiconductor memory of the present invention. The sector protection implemented by the circuit is achieved by two bits, one of which is PPB stored in a non-volatile cell for each sector, and the other being DPB stored in a volatile cell for each sector. One PPB and one DPB may be provided to each sector group consisting of multiple sectors (for example, four sectors). In this case, protection of each sector group is achieved by one PPB provided for each sector group and one DPB for each sector group.

A DPB circuit 11 forms a volatile memory section, and a PPB circuit 12 forms a non-volatile memory section. The DPB circuit 11 has DPB cells (DPB1-DPBn), each of which is associated with the respective sector. The PPB circuit 12 has PPB cells (PPB1-PPBn), each of which is associated with the respective sector. The PPB cells and DPB cells may be arranged in rows and columns. In the example shown in FIG. 1, the DPB circuit 11 and the PPB circuit 12 form columns, and cells in these circuits form rows.

The outputs (DPBOUT and PPBOUT) of the DPB circuit 11 and the PPB circuit 12 are applied to drain terminals of p-MOS transistors 17 and 18 in each of which the gate terminal is grounded and the source terminal is supplied with a power supply voltage Vcc. The DPB circuit 11 and the PPB circuit 12 perform signal processing that will be described later, and realize sector protection for inhibiting hardware-oriented programming/erasing of the corresponding sector. Each of the DPBs in the DPB circuit 11 and each of the PPBs in the PPB circuit 12 can be selected by a decoder (not shown) connected to the sector protection circuit, wherein the decoder will be described later.

When the selected sector is in the protected state, the DPB cell associated with the sector outputs a low-level signal, and the PPB cell associated therewith outputs a high-level signal. In contrast, when the selected selector is in the unprotected state, the DPB cell associated with the sector outputs a high-level signal, and the PPB cell associated therewith outputs a low-level signal.

The output signal DPBOUT from the DPB circuit 11 passes through an inverter 19, and an inverted signal DPBOUTB is applied to one terminal of a NOR gate 16. The output signal PPBOUT from the PPB circuit 12 is applied to one terminal of an AND gate 15 connected to the other input terminal of the NOR gate 16.

The sector protection circuit of the present invention is capable of accepting a PPBDIS signal that disables a transfer of sector protection information by any of the PPB cells. The PPBDIS signal is supplied from a command register (not shown) in response to a command input (first command). When the PPBDIS signal is at the high level, the transfer of the sector protection information from any of the PPB cells is disabled. When the PPBDIS signal is at the low level, the sector protection information is validly transferred.

In addition to the PPBDIS signal, the sector protection circuit can accept a PPBLOCK signal output from a PPB lock circuit (not shown). A register is provided in the PPB lock circuit, and the setting of the register is carried out by a command input (second command). The PPBLOCK signal represents the content of the register. The PPBLOCK signal allows and inhibits the rewriting of the PPB cells. When the PPBLOCK signal is at the high level, the function of “disabling the transfer of the sector protection information by the PPB cells” is disabled and the transfer of the sector protection information by the PPB cells is thus enabled in order to inhibit the rewriting of the PPB cells. Thus, the sectors that are in the protected state by the associated PPB cells are maintained at the high protection level. In contrast, when the PPBLOCK signal is at the low level, the function of “disabling the transfer of the sector protection information by the PPB cells” is enabled.

The PPBLOCK signal is input to a NOT gate 13, which outputs the high-level signal for the low level of the PPBLOCK signal (enabling the rewriting of the PPB cells) and the low-level signal for the high level of the PPBLOCK signal (inhibiting the rewriting of the PPB cells).

The output signal of the NOT gate 13 is input to one terminal of a NAND gate 14, and the other terminal thereof is supplied with the PPBDIS signal.

The NAND gate 14 performs the logical operation on the PPBDIS signal and the PPBLOCK signal. Then, the NAND gate 14 outputs the low-level signal when both the PPBDIS signal and the PPBLOCK signals are at the high level, and outputs the high-level signal when either one of these signals is at the low level. That is, the NAND gate 14 outputs the low-level signal only when the PPBDIS signal is in the state of “disabling the transfer of the sector protection information by the PPB cells” and the PPBLOCK signal enables the rewriting of the PPB cells. In other cases, the NAND gate 14 outputs the high-level signal.

The output signal of the NAND gate 14 is applied to one terminal of the AND gate 15, which receives, via the other terminal, the signal PPBOUT from the PPB circuit 12. Then, the AND gate 15 performs the logical operation on the received signals. The AND gate 15 outputs the high-level signal only when the output signal of the NAND gate 14 and the signal PPBOUT from the PPB circuit 12 are both at the high level. That is, the AND gate 15 outputs the high-level signal only when at least one of the PPBDIS signal and the PPBLOCK signal is either in the state of “enabling the transfer of the sector protection information by the PPB cells” or “inhibiting the rewriting the PPB cells” (the output of the NAND gate 14 is at the high level) under the condition that the selected sector is in the protected state by the PPB cell associated therewith.

The output of the AND gate 15 is applied to one terminal of the NOR gate 16, which receives, via the other terminal, the signal DPBOUTB from the DPB circuit 11. Then, the NOR gate 16 performs the logical operation on the received signals. The NOR gate 16 outputs the high-level signal only when the output signal of the AND gate 15 and the signal DPBOUTB from the DPB circuit 11 are both at the low level. That is, the NOR gate 16 outputs the high-level signal only when at least one of the PPBOUT signal and the output signal of the NAND gate 14 is not in the state protected state by the PPB cell associated with the selected sector, or is in the state of enabling the rewriting of the PPB cells and is not in the protected state by the DPB cell associated with the selected sector under the condition that the transfer of the sector protection information by the PPB cells is disabled (the output of the AND gate 15 is at the low level).

In the above-mentioned manner, the sector protection circuit outputs the signal SPB for sector protection to a circuit for controlling the states of the sectors (a state control circuit, not shown).

The DPB circuit 11 equipped with the DPB cells sets the signal DPBOUT to the low level when the selected sector is in the protected state, whereby the signal SPB is at the low level. Thus, the information indicating that the selected sector is in the protected state is transferred to the state control circuit, so that programming/erasing of the selected sector is inhibited.

The PPB circuit 12 equipped with the PPB cells sets the high-level signal PPBOUT when the selected sector is in the protected state, so that the sector protection information based on the PPB cells is available. However, due to the presence of the NAND gate 14 for the signals PPBDIS and PPBLOCK, the sector protection information cannot be transferred from the PPB circuit 12 when the signal PPBDIS (which enables and disables the transfer of the sector protection information by the PPB cells) is at the high level. Thus, only the sector protection information stored in the DPB cells that are volatile cells can be selectively enabled.

However, in case where information for inhibiting the rewriting of PPB is set in the register in the PPB lock circuit, the PPBLOCK signal is at the high level and the PPBDIS signal (disabling a transfer of the sector protection information by the PPB cells) is thus disabled, so that the sector protection information in the PPB cells can be validly transferred.

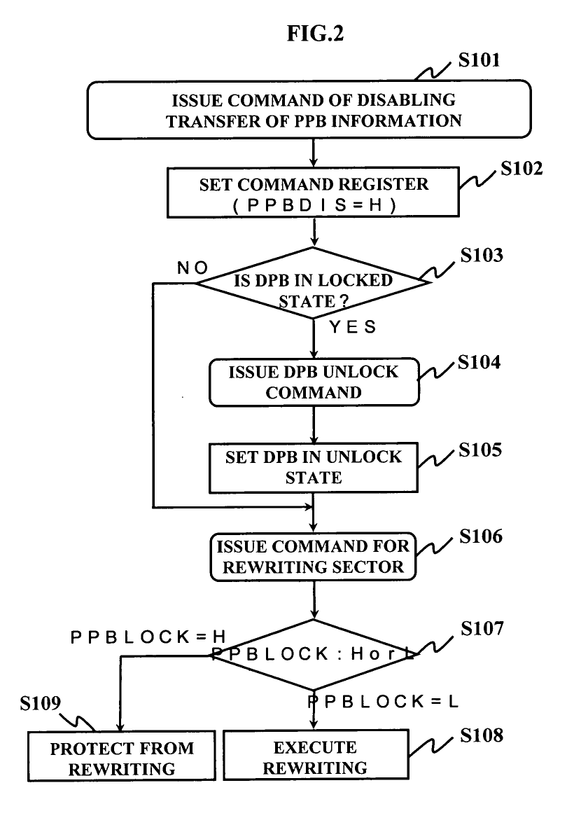

FIG. 2 is a flowchart of a sequence of rewriting a sector in a case where the sector is selected for rewriting and the PPB cell associated with this sector stores the sector protection information, wherein the sequence is realized by the sector protection circuit of the present invention.

A command is issued which disables a transfer of the sector protection information stored in the PPB cells (step S101). The command register outputs the PPBDIS signal that is at the high level (step S1102).

When the sector protection information is stored in the DPB cell associated with the selected sector (YES at step S103), a new command is issued (step S104) so that the protection information in the DPB cell is unlocked (step S105). In contrast, when the sector protection information is not stored in the DPB cell (NO at step S103), the process proceeds to step S106.

A command for programming or erasing is issued against the sector of concern (step S106). When the rewriting of the PPB cells is not inhibited (PPBLOCK=L at step S107), the rewriting of the sector is executed (step S108). In contrast, when the rewriting of the PPB cells is inhibited (PPBLOCK=HAT at step S107), the rewriting of the sector is not executed but is protected from rewriting (step S109).

In an alternative, a command for disabling the transfer of the sector protection information stored in the PPB cells may be issued after the protection information in the DPB cells are unlocked.

In the above-mentioned manner, the user can easily rewrite the sector even when the protection information is stored in the associated PPB cell.

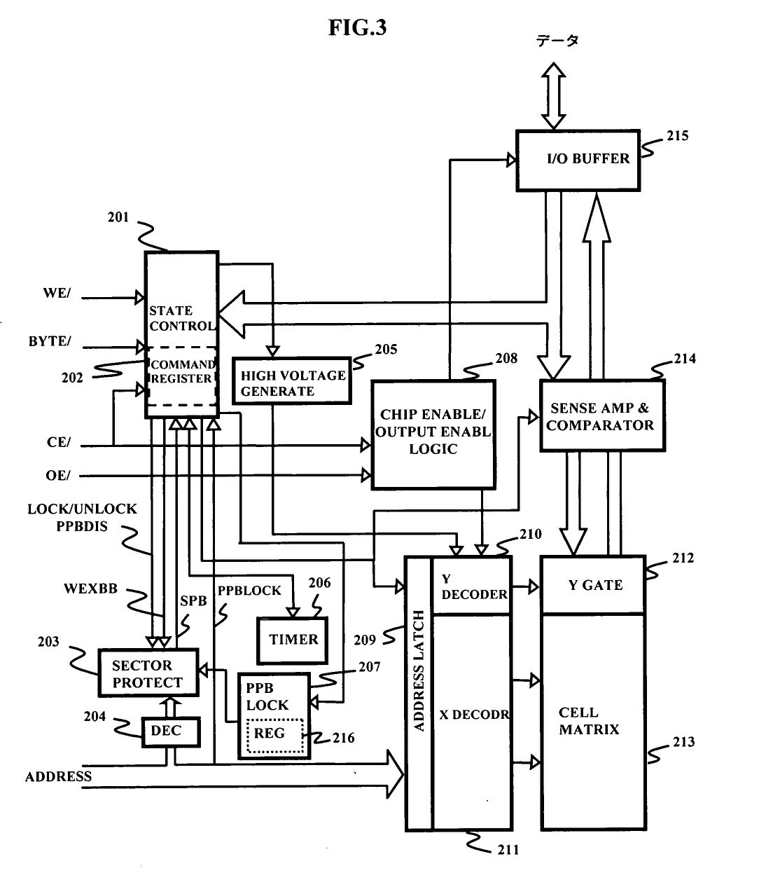

FIG. 3 is a block diagram of a non-volatile semiconductor memory in which the above-mentioned sector protection circuit is incorporated. Referring to this figure, a symbol /WE is a write enable signal for write control, /BYTE is a byte signal, /CE is a chip enable signal for selecting a chip to be accessed, and /OE is an output enable signal used to control outputting from the selected signal. The signals /WE, /BYTE, and /CE are supplied to a state control circuit 201 equipped with a command register 202, and the signals /CE and /OE are supplied to a logic circuit 208, which controls outputting from the chip.

The state control circuit 201 and the command register 202 are supplied with the control signals /WE, /BYTE and /CE externally supplied, an address signal supplied via an address bus, and a data signal supplied via a data bus, and control reading, programming, erasing and sector protection for an internal circuit.

The state control circuit 201 supplies a high-voltage generating circuit 205, which generates programming/erasing voltages with which programming and erasing are carried out. The state control circuit 201 drives a Y decoder 210 and an X decoder 211 controlled by an address latch 209. The state control circuit 201 exchanges signals with a timer 206 to manage a control time.

The non-volatile semiconductor memory is equipped with a cell matrix 213 in which cells are arrayed. The cell matrix 213 has sectors, each of which may have cells arranged in rows and columns.

The X decoder 211, which is a row decoder of the cell matrix 213, receives the address externally generated or a part thereof, and selects and activates one of the rows of memory cells on the sector basis.

The X decoder 211 receives the address via the address bus, and selects one of the row lines designated by the address. Then, the X decoder 211 sets the selected row line to a given voltage for activating the cells connected thereto, and sets these row line to another voltage level for inactivating the memory cells connected to other row lines on which voltages may appear.

A Y gate 212 responds to a signal from the Y decoder 212, and selects one of the column lines designated by the signal.

The present memory has a sense amplifier/comparator 214, which sense a voltage level on the column line corresponding to data stored in the memory cell accessed by addressing, and compares the sensed voltage level with a given reference voltage, a comparison result being output.

The present memory is equipped with an I/O buffer 215 for data inputting and outputting. The I/O buffer 215 is connected to the sense amplifier 214, and couples the accessed memory cell with I/O data pins, which are not shown.

A sector protection circuit 203 according to the present invention selects one of the DPB cells in the DPB circuit 11 and one of the PPB cells in the PPB circuit 12 in accordance with signals WSZH(h) and WSZV(v) from a decoder 204 connected to the address bus. The sector protection implemented by the above circuit is realized by two bits, one of which is the PPB stored in the non-volatile cell for each sector and the other being DPB stored in the volatile cell for each sector. Alternatively, a pair of PPB and DPB may be assigned to a group of multiple sectors (for example, four sectors) in order to realize the sector protection. In this case, the sector protection is realized by one PPB assigned to each sector group and one DPB assigned to each sector group.

The sector protection circuit 203 is supplied, based on the command input, with a LOCK/UNLOCK signal for the setting of the DPB cells, the PPDDIS signal supplied from the command register 202, and a write control signal WEXBB supplied therefrom. The sector protection circuit 203 processes the above signals, and outputs a resultant signal to the state control circuit 201 as the SPB signal. A PPB lock circuit 207 equipped with a register 216 outputs information previously stored in the register 216 to the sector protection circuit 203.

In the non-volatile semiconductor memory of the present invention, the DPB circuit provided in the second protection circuit 203 sets the DPBOUT to the low level and thus SPB to the low level when the sector selected by the command is in the protected state. Then, the information indicating that the selected sector is in the protected state is transferred to the state control circuit, so that the programming and erasing of the sector can be inhibited.

The PPB circuit provided in the sector protection circuit 203 sets the PPBOUT to the high level when the sector selected by the command is in the protected state, so that the sector protection information becomes available. However, the NAND gate for PPBDIS and PPBLOCK is added, so that the sector protection information from the PPB circuit is inhibited from being transferred when the PPBDIS related to the command input is at the high level. It is to be noted that if information for inhibiting the rewriting of PPB is defined, the PPBLOCK switches the high level, and the function of PPBDIS is disenabled.

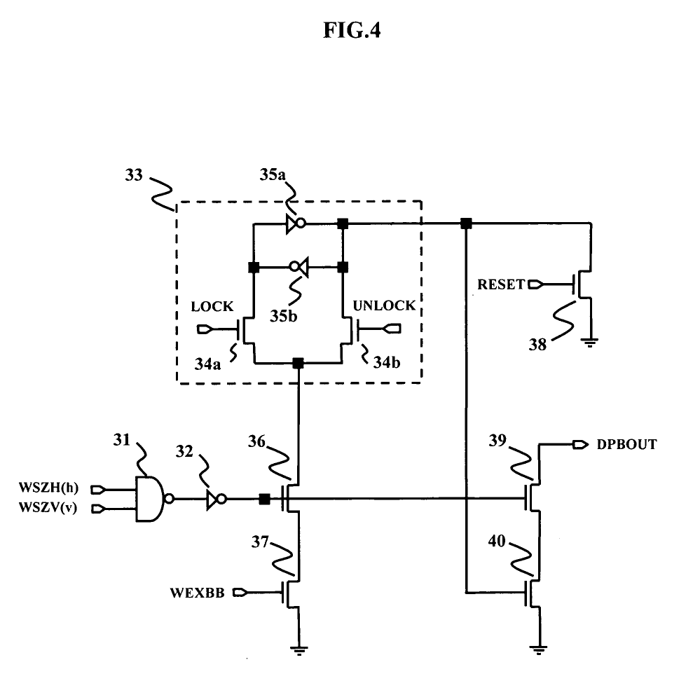

FIG. 4 is a circuit diagram of any one of the DDP cells that form the DPB circuit. The outputs (WSZH(h), WSZV(v)) from the decoder, which are the DPB select signals, are applied to a NAND gate 31, which outputs the low-level only when the WSZH(h) and WSZV(v) are both at the high level. The output of the NAND gate 31 is input to a NOT gate 32, which outputs the high-level signal for the low level of the input signal and the low-level signal for the high level of the input signal. The output signal of the NOT gate 32 is applied to gate terminals of MOS transistors 36 and 39.

The DPB set circuit 33 sets the DPB in accordance with the LOCK signal and the UNLOCK signal from the state control circuit 201 based on the command input. The DPB set circuit 33 is a flip-flop circuit composed of two MOS transistors (34a, 34b) and two inverters (35a, 35b). The LOCK signal is applied to the gate terminal of the MOS transistor 34a, and the UNLOCK signal is applied to the gate terminal of the MOS transistor 34b. The DPB may be reset by applying a reset signal RESET from the state control circuit 201 to the MOS transistor 38.

The DPB set circuit 33 outputs a pulse signal based on switching of the two MOS transistors 34a and 34b between ON and OFF. The pulse signal is then applied to the gate terminal of a MOS transistor 40 connected to the MOS transistor 39, and the drain terminal of the MOS transistor 38 supplied with the reset signal RESET. The writing of the DPB is carried out by applying the write signal WEXBB from the state control circuit 201 to the gate terminal of the transistor 37.

The protection/unprotection of the DPB cells is designated by issuing the command. When the /WE pin is switched to the low level after issuance of the command, the signal WEXBB switches to the high level, and the writing of the sector selected by WSZH(h) and WSZV(v) based on the LOCK/UNLOCK state is performed during that time.

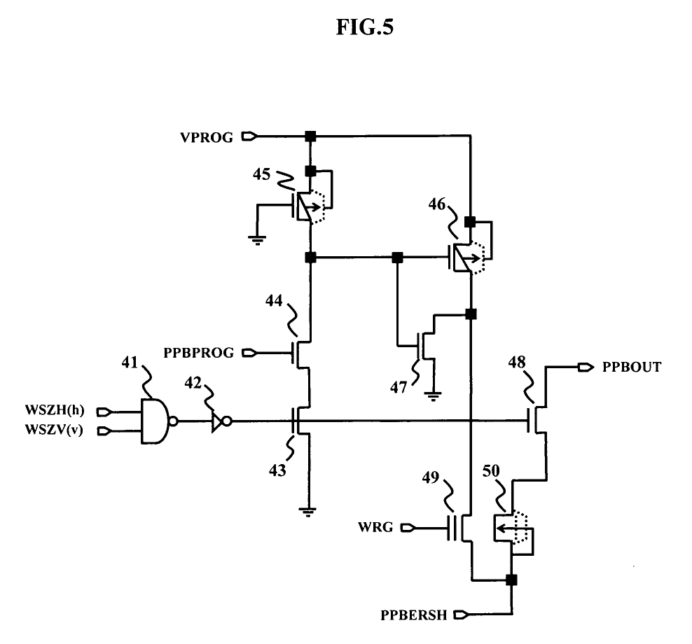

FIG. 5 is a circuit diagram of any one of the PPB cells that form the PPB circuit. The outputs (WSZH(h) and WSZV(v)) from the decoder that form the PPB select signal are applied to the NAND gate 41, which outputs the low-level signal only when WSZH(h) and WSZV(v) are both at the high level. The output of the NAND gate is applied to a NOT gate 42, which outputs the high-level signal when the input signal is at the low level and outputs the low-level signal when tie input signal is at the high level. The output of the NOT gate 42 is applied to the gate terminals of the MOS transistors 43 and 48.

The writing of the PPB cells are carried out for every cell in accordance with a program command supplied from the outside of the memory in such a manner that the high voltage is applied to a terminal VPROG and a high voltage is applied to a gate terminal WRG for writing/reading associated with the cell selected by WSZH(h) and WSZV(v) by a signal PPBPROG. The erasing of the PPB cells is carried out by applying a negative high voltage to the gate terminal WRG and a positive high voltage to an external input terminal PPBERSH for erasing.

The gate terminal WRG for writing/reading is connected to MOS transistors 49 and 50, which have a charge storage layer like the core cells, and share a charge storage layer and a control gate connected to the terminal WRG. Each of the MOS transistors 49 and 50 has the respective drain terminal. The transistor 49 is used for programming, and the transistor 50 is used for reading. The terminal VPROG for programming is connected to the source terminals of the two P-channel MOS transistors 45 and 46. The drain terminal of the P-channel MOS transistor 45 is connected to the gate terminal of the P-channel MOS transistor 46, and the drain terminal of the P-channel MOS transistor 46 is connected to the drain terminal of the MOS transistor 49. The voltage corresponding to the signal PPBPROG is applied to the gate of the MOS transistor 44 connected in series to the MOS transistor 43, and the output of the MOS transistor 44 is applied to the gate of the P-channel MOS transistor 46. The node PPBERSH is common to all the PPB cells, which are erased all at once.

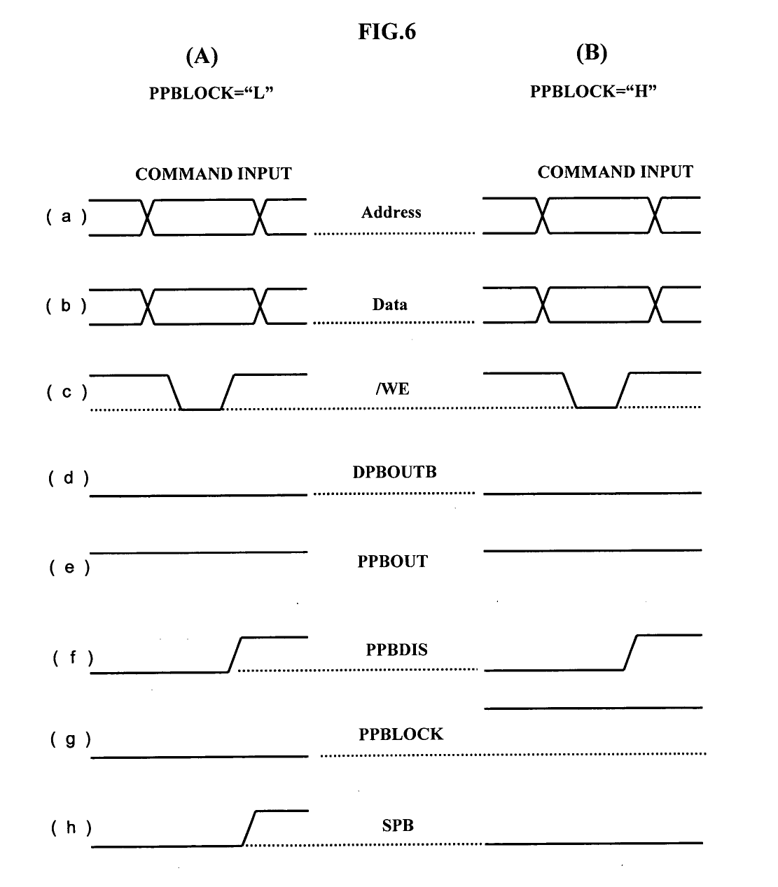

FIG. 6 is a timing chart of an operation of the sector protection circuit according to the present invention. As has been described previously, when the selected sector is in the protected state, the DPB cell associated with the selected sector outputs the low-level signal, and the PPB cell outputs the high-level signal.

In contrast to the above, when the selected sector is in the unprotected state, the DPB cell associated with the selected sector outputs the high-level signal, and the PPB cell outputs the low-level signal. In the timing chart shown, the signal DPBOUTB is at the low level, and the signal PPBOUT is at the high level, so that the selected sector is in the protected state.

The transfer of the sector protection information by the PPB cells is disabled when the PPBDIS signal is at the high level, and is enabled when the PPBDIS signal is at the low level.

As is shown in the timing chart, the level of the PPBDIS signal changes from the enable state in which the sector protection information by the PPB cells can be validly transferred to the disabled state in synchronism with the write control signal /WE.

At that time, when the PPBLOCK signal is at the low level (FIG. 6A), the function of “disabling the transfer of the sector protection information by the PPB cells” by the PPBDIS signal is enabled, and the signal SPB at the high level is thus output.

In contrast, when the PPBLOCK signal is at the high level (FIG. 6B), the function of “disabling the transfer of the sector protection information by the PPB cells” by the PPBDIS signal is disabled, and the signal SPB at the low level is thus output.

That is, when the PPBLOCK signal is at the low level (FIG. 6A), the SPB signal that is the sector protection signal switches to the high level. In contrast, when the PPBLOCK signal is at the high level (FIG. 6B), the SPB signal is maintained at the low level.

Table 1 shows the contents of the cells involved in execution of the sector protection by the sector protection circuit according to the present invention, in which “0” denotes the sector unprotected state, and “1” denotes the sector protected state.

TABLE 1

| | | | SECTOR | | |
|---|---|---|---|---|---|
| | | | PROTECTED | PPB LOCK | SECTOR PROTECTTNG BIT IN |
| CASE | DPB | PPB | STATE | BIT SET | PPB DISABLED STATE |
| 1 | 0 | 0 | NO | NO | — |
| 2 | 1 | 0 | YES | NO | DPB |
| 3 | 0 | 1 | YES | NO | — |
| 4 | 1 | 1 | YES | NO | DPB |
| 5 | 0 | 0 | YES | YES | — |
| 6 | 1 | 0 | YES | YES | DPB |
| 7 | 0 | 1 | YES | YES | DPB |
| 8 | 1 | 1 | YES | YES | DPB&PPB |

As described above, the non-volatile semiconductor memory according to the present invention employs the command for enabling only IDPB data in the case where at least one of the PPB of the non-volatile cell defined on the sector basis and the DPB of the volatile cell defined on the sector basis is in the programmed state. This makes it possible to rewrite the sector without erasing the PPB cells all at once.

When the PPBLOCK that inhibits the rewriting of PPB is set, the command of enabling only DPB data is disabled.

The present invention provides the non-volatile semiconductor memory capable of rewriting the sectors without erasing the PPB cells. The present invention is not limited to non-volatile semiconductor memory devices that primarily store information like flash memories, but includes a semiconductor device having the non-volatile semiconductor memory as a part of the device like a system LSI.

1. A sector protection circuit comprising:
a non-volatile storage section storing data indicating sector protection/unprotection for each sector or each sector group;
a volatile storage section storing data indicating sector protection/unprotection for each sector or each sector group; and
a circuit enabling only the data stored in the volatile storage section in response to a first command related to a sector or sector group in a state in which said sector or sector group is protected from programming and erasing when at least one of the non-volatile and volatile storage sections stores data indicating that said sector or sector group should be protected.

2. The sector protection circuit as claimed in claim 1, wherein the circuit comprises a circuit that performs a logical operation on the data stored in the non-volatile storage section, the data stored in the volatile storage section, and a signal associated with the first command.

3. The sector protection circuit as claimed in claim 1, wherein the circuit comprises a circuit that blocks a transfer of the data from the non-volatile storage section when receiving the first command.

4. The sector protection circuit as claimed in claim 1, wherein the circuit disables the first command when a signal that inhibits the data in the non-volatile storage section from being rewritten is set.

5. The sector protection circuit as claimed in claim 1, wherein the circuit disables the first command when receiving a second command that instructs the data in the non-volatile storage section to be programmed.

6. The sector protection circuit as claimed in claim 1, wherein the circuit comprises a circuit that performs a logical operation on the data in the non-volatile storage section, the data in the volatile storage section, a signal associated with the first command, and another signal associated with a second command that inhibits the data in the non-volatile storage section from being rewritten.

7. The second protection circuit as claimed in claim 1, wherein all data in the non-volatile storage section are erased concurrently.

8. A sector protection circuit comprising:
a non-volatile storage section storing data indicating sector protection/unprotection for each sector or each sector group;
a volatile storage section data indicating sector protection/unprotection for each sector or each sector group; and
a circuit that disables data stored in the non-volatile storage section and enables data in the volatile storage section when receiving a first command.

9. The sector protection circuit as claimed in claim 8, wherein the circuit disables the first command when receiving a second command.

10. The sector protection circuit as claimed in claim 9, wherein the second command inhibits the data in the non-volatile storage section from being rewritten.

11. A semiconductor device comprising a memory array having sectors composed of non-volatile memory cells; and
a sector protection circuit that protects the sectors from programming and erasing,
the sector protection circuit comprising:
a non-volatile storage section storing data indicating sector protection/unprotection for each sector or each sector group;
a volatile storage section storing data indicating sector protection/unprotection for each sector or each sector group; and
a circuit enabling only the data stored in the volatile storage section in response to a first command related to a sector or sector group in a state in which said sector or sector group is protected from programming and erasing when at least one of the non-volatile and volatile storage sections stores data indicating that said sector or sector group should be protected.

12. A sector protection method comprising the steps of:
protecting, in the absence of a given command, a sector or sector group when data indicating that said sector or sector group should be protected is stored in at least one of a non-volatile storage section storing data indicating sector protection/unprotection for each sector or each sector group and a volatile storage section storing data indicating sector protection/unprotection for each sector or each sector group; and
enabling only data in the volatile storage section in response to the given command input.

13. The sector protection method as claimed in claim 12, further comprising a step of disabling the given command when receiving another command that inhibits the data in the non-volatile storage section from being rewritten.
